(19) United States
(12) Patent Application Publication
(10) Pub. No.: US 2008/0217689 A1
(43) Pub. Date: Sep. 11, 2008

(54) SEMICONDUCTOR DEVICES HAVING SILICON-ON-INSULATOR (SOI) SUBSTRATES AND METHODS OF MANUFACTURING THE SAME

(76) Inventors: Yong-Hoon Son, Gyeonggi-do (KR); Hye-Ran Choi, Gyeonggi-do (KR); Jong-Wook Lee, Gyeonggi-do (KR)

Correspondence Address: MYERS BIGEL SIBLEY & SAJOVEC, PO BOX 37428, RALEIGH, NC, 27627, US

(21) Appl. No.: 12/040,024

(22) Filed: Feb. 29, 2008

(30) Foreign Application Priority Data
Mar. 5, 2007 (KR) 2007-21375

(51) Int. Cl. H01L 27/04; H01L 21/336

(52) U.S. Cl. 257/347; 438/197; 257/E27.112; 257/E21.409

(57) ABSTRACT

Semiconductor devices are provided including gate patterns on a substrate and isolation regions on the substrate. Insulating patterns are provided in the substrate below the gate patterns. Source/drain regions are provided in the substrate. Related methods of fabricating semiconductor devices are also provided.

### CLAIM OF PRIORITY

This application claims priority from Korean Patent Application No. 10-2007-0021375 filed on Mar. 5, 2007 in the Korean Intellectual Property Office, the disclosure of which is incorporated herein by reference in its entirety.

### FIELD OF THE INVENTION

The present invention relates generally to semiconductor devices and, more particularly, to semi conductor device having Silicon-On-Insulator (SOI) substrates and method of fabricating the same.

### BACKGROUND OF THE INVENTION

Semiconductor devices having silicon-on-insulator (SOI) substrates may operate at high speeds and provide transistors having good channel characteristics and small amounts of leakage current. Therefore, recently the use of SOI semiconductor substrates has increased. It is relatively more difficult to manufacture SOI semiconductor substrates than silicon semiconductor substrates. Furthermore, SOI semiconductor substrates may experience short channel effect, which may cause deterioration due to insufficient radiation of heat caused by movement of carriers.

To address some of the drawbacks of SOI substrates, insulating patterns having an island shape may be formed on a silicon layer in a substrate, or silicon patterns having an island shape on an insulating layer in a substrate. A substrate having such a structure can reduce leakage current in a silicon region due to the insulating patterns, and can improve the thermal characteristic of a semiconductor device because heat generated during operation of the device can be rapidly transferred to a bulk of a corresponding substrate due to the silicon patterns.

### SUMMARY OF THE INVENTION

Some embodiments of the present invention provide semiconductor devices comprising gate patterns on a substrate and isolation regions on the substrate. Insulating patterns are provided in the substrate below the gate patterns. Source/drain regions are provided in the substrate.

In further embodiments of the present invention, bottom surfaces of the insulating patterns may be relatively closer to a surface of the substrate than bottom surfaces of the isolation regions.

In still further embodiments of the present invention, upper surfaces of the insulating patterns may be spaced apart by a first distance from a surface of the substrate. A channel region may be formed in the spaced apart regions having the first distance. The first distance may be electrically isolated from a bulk region of the substrate.

In some embodiments of the present invention, the insulating patterns may have an upper horizontal width and a lower horizontal width, the upper horizontal width being longer than the lower horizontal width. The insulating patterns may have an island shape. The insulating patterns may have a wider width than a width of a gate electrode of each of the gate patterns.

In further embodiments of the present invention, the bottom surfaces of the source/drain regions may be deeper toward an interior of the substrate than upper surfaces of the insulating patterns.

In still further embodiments of the present invention, the insulating patterns may be aligned with the gate patterns.

Although embodiments of the present invention are discussed above with respect to semiconductor devices, methods of fabricating semiconductor devices are also provided herein.

### BRIEF DESCRIPTION OF THE DRAWINGS

FIGS. 1 through 5 are cross-sections illustrating semiconductor devices according to some embodiments of the present invention.

FIGS. 6 through 16 are cross-sections illustrating processing steps in the fabrication of semiconductor devices according to some embodiments of the present invention.

### DETAILED DESCRIPTION OF EMBODIMENTS OF THE INVENTION

Embodiments of the invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The technology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

Example embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

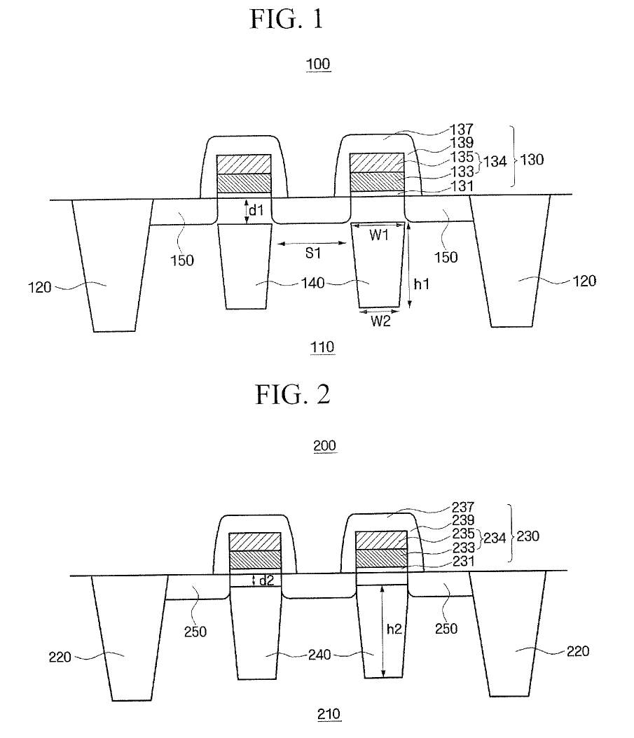

Referring first to FIG. 1, cross-sections schematically illustrating semiconductor devices according to some embodiments of the present invention will be discussed. As illustrated in FIG. 1, a semiconductor device 100 includes gate patterns 130 on a substrate 110, isolation regions 120, insulating patterns 140, and source/drain regions 150. The substrate 110 includes, for example, a silicon wafer or a silicon-geranium (SiGe) wafer.

The isolation regions 120 according to some embodiments of the present invention are illustrated and described as a shallow trench isolation (STI) region. That is, the isolation regions 120 may include a different insulating material or shape that has a function of electrically isolating an active region in which a transistor is formed.

As further illustrated, the gate patterns 130 include gate insulating layers 131, gate electrodes 134, gate capping layers 137, and gate spacers 139. The gate insulating layers 131 according to some embodiments of the present invention may include silicon oxide layers, but embodiments of the present are not limited thereto. In further embodiments, the gate insulating layers 131 may include a different insulating layer, such as aluminum oxide layers, hafnium oxide layers, and the like.

The gate electrodes 134 include a multi-layered electrode, such as upper gate electrodes 133 and lower gate electrodes 135, however, embodiments of the present invention are not limited thereto. According to some embodiments of the present invention, the gate electrodes 134 include lower gate electrodes 133 including polycrystalline silicon, and upper gate electrodes 135 including metallic silicide, such as tungsten suicide (WSi), titanium silicide (TiSi), nickel silicide (NiSi), and the like, which are some of the various examples. The gate electrodes 134 may include signal material. For example, the gate electrodes 134 may include only polycrystalline silicon, only metallic silicide, or only metal. The gate capping layers 137 may be used as a patterning mask to pattern the gate insulating layers 131 and gate electrodes 134. Furthermore, the gate capping layers 137 can protect the gate electrodes 134 during a subsequent etch process. According to some embodiments of the present invention, the gate capping layers 137 include a silicon nitride layer, however, embodiments of the present invention is not limited thereto. The gate capping layers 137 may include a single layer or multiple layers of various insulating material, as well as a silicon oxide Layer, a silicon oxy-nitride layer, and the like.

The gate spacers 139 may include materials which are the same as or similar to that of the gate capping layers 137. According to some embodiments of the present invention, the gate spacers 139 include the silicon nitride layer, however, embodiments of the present invention are not limited thereto. Similar to the gate capping layers 137, the gate spacers 139 may include a single layer or multiple layers of various insulating material as well as a silicon oxide layer, a silicon oxy-nitride layer, and the like. In embodiments of the present invention where the gate spacers 139 include a silicon oxide layer, the gate spacers 139 may be conformably formed on the surface of the substrate 110, and the surfaces and lateral faces of the gate insulating layers 131 and gate electrodes 134. As used herein, “conformably” refers to an overall thickness that is substantially uniform. The gate spacer 139 may have an “L.” In embodiments of the present invention, a first gate spacer having the shape of “L” includes a silicon oxide layer, a second gate spacer of silicon nitride-based material may additionally be formed on the first gate spacer. Thus, in some embodiments of the present invention, the gate spacer 139 may include multiple layers.

The insulating patterns 140 may be formed in the substrate 110 in accordance with the gate patterns 130. In particular, the insulating patterns 140 may be formed in the substrate 110 so as to be aligned with the gate patterns 130. According to some embodiments of the present invention, the insulating patterns 140 may be formed to have an upper width “W1” that is similar to the width of the gate electrodes 134. In embodiments of the present invention where the upper width “W1” of the insulating patterns 140 is similar to the width of the gate electrodes 134, as described above, the insulating patterns 140 can correspond to a lower portion of a channel region to be formed beneath the gate insulating layers 131. In particular, the insulating patterns 140 are formed to have an upper width “W1” similar to a length of a channel region. However, it is not essential that the upper “W1” of the insulating patterns 140 correspond to the length of the channel region. Depending on the characteristics of a desired semiconductor device, the space “S1” of the insulating patterns 140 may be formed to be greater than the width of the one of gate spacers 139. However, when the insulating patterns 140 are formed beneath the channel region, the characteristics of the semiconductor device can be greatly improved. In some embodiments of the present invention, the space “S1” between the insulating patterns 140 is greater than “0” (S1>0).

Furthermore, the insulating patterns 140 may be spaced from a boundary between the gate patterns 130 and the surface of the substrate 110 by a first distance “d1” of a predetermined depth. In the first distance “d1,” the channel region of a transistor is formed.

The insulating patterns 140 according to some embodiments of the present invention allow the substrate 110 to have the characteristics of an SOI semiconductor substrate. As described above, the SOI substrate may have advantages in that a leakage current is small and a transistor operates at a high speed, but may have a disadvantage in that heat generated upon an operation of a transistor is not efficiently radiated to the outside. In contrast, the insulating patterns 140 according to some embodiments of the present invention, which correspond to an insulating layer, may reduce leakage current and can radiate heat to spaces between the insulating patterns 140 and to spaces between the insulating patterns 140 and the isolation regions 120, thereby having the advantages of both a general substrate and the SOI substrate. In this case, such characteristics may be defined by the widths “W1” and “W2,” height “h” and space “S1” of the insulating patterns 140. Generally, as the upper/lower widths “W1” and “W2” and height “h1” of the insulating patterns 140 increase, the leakage current of a transistor decreases and faster operation is achieved, but the heat radiation characteristic becomes worse and worse, thereby degrading the reliability of the semiconductor device and shortening the lifetime thereof. In contrast, as the upper/lower widths “W1” and “W2” and height “h1” of the insulating patterns 140 decrease, the leakage current of a transistor increases and the operation speed decreases, even though the heat radiation characteristic becomes better. Therefore, the upper/lower widths “W1” and “W2” and height “h1” of the insulating patterns 140, and the space “S1” therebetween may be established to various values depending on the characteristics of each desired semiconductor device.

The height “h1” of the insulating patterns 140 is less than that of the isolation regions 120. Furthermore, the insulating patterns 140 may be formed in such a maimer that the bottom ends thereof is nearer to the surface of the substrate 110 than the bottom ends of the isolation regions 120. This is because the insulating patterns 140 have a smaller size than the isolation regions 120 so that it is unnecessary for the insulating patterns 140 to be formed deep into the substrate 110.

Furthermore, according to various embodiments of the present invention, the upper width “W1” of the insulating patterns 140 is formed to be wider than the lower width “W2” of the insulating patterns 140, which facilitates the forming process thereof.

The source/drain regions 150 may be formed with various concentrations and depths. In general, the concentration and depth of the source/drain regions 150 is influenced by the size of the gate patterns 130. Therefore, when the insulating patterns 140 are formed below the gate patterns 130, the source/drain regions 150 can be formed with a higher concentration up to a deeper location. In some embodiments of the present invention, an effect of reducing of a time period for forming a channel or an effect of lowering the resistance of a formed channel can be expected, which will be discussed further herein. FIG. 1 illustrates embodiments in which the source/drain regions 150 are formed up to a location similar to or a little deeper than the top surfaces of the insulating patterns 140.

Depending on the depth of the source/drain regions 150, the first distance “d1” region, in which a channel is formed, and a bulk region of the substrate 110 may be electrically either conducted with each other or are cut off. Since the depths of the source/drain regions 150 illustrated in FIG. 1 have a level similar to the top surfaces of the insulating patterns 140, it is difficult to exactly define whether the region for forming a channel and the bulk region of the substrate 10 are electrically conducted with each other or are cut off.

Although not illustrated, the semiconductor device 100 according to some embodiments of the present invention has no discontinuity in a crystal structure face, at least in the channel region. If there is a discontinuity in the crystal structure of the semiconductor device 100, the discontinuity is formed in the source/drain regions 150; particularly only in a source/drain region formed between the insulating patterns 140, which will be discussed further herein.

Referring now to FIG. 2, a cross-section illustrating a semiconductor device according to some embodiments of the present invention. As illustrated in FIG. 2, the semiconductor device 200 includes gate patterns 230 on a substrate 210, isolation regions 220, insulating patterns 240, and source/drain regions 2. The insulating patterns 240 are formed so as to have a top surface with a shallower depth from the surface of the substrate 210 than that in the semiconductor device 100. A second distance “d2,” that is a distance from the surface of the substrate 210 to the top surfaces of the insulating patterns 240, is shorter than the first instance “d1.” Accordingly, the source/drain regions 250 are formed toward the bulk up to a deeper location than the top surfaces of the insulating patterns 240. In these embodiments of the present invention, when a transistor is tun-ed on, the time required to form a channel can be shortened. It is clear that as the time required to form a channel becomes shorter, a higher-speed operation can be achieved. Furthermore, when the region for forming a channel is completely separated from the bulk region, as shown in FIG. 2, an additional leakage current reduction effect may be expected.

The semiconductor device 200 according to some embodiments of the present invention has no discontinuity in a crystal structure, at least in the channel region.

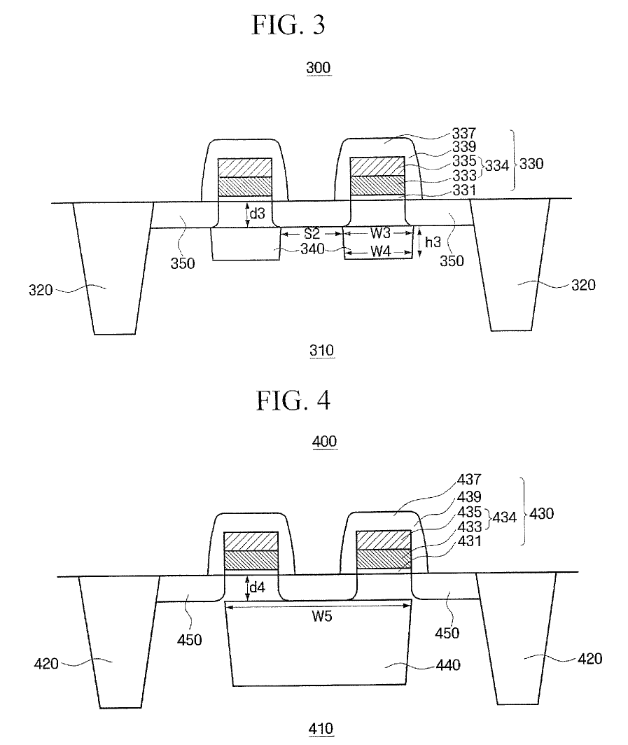

Referring now to FIG. 3, a cross-section illustrating semiconductor devices according to some embodiments of the present invention. As illustrated in FIG. 3, the semiconductor device 300 includes gate patterns 330 on a substrate 310, isolation regions 320, insulating patterns 340, and source/drain regions 350. In the semiconductor device 300 the insulating patterns 340 are formed so as to have a top surface with a deeper depth from the surface the substrate 310 than those of the semiconductor devices 100 and 200. A third distance “d3,” which is the distance from the surface of the substrate 310 to the top surfaces of the insulating patterns 340, is greater than the first distance “d1.” Accordingly, the source/drain regions 350 are formed at higher location than the top surfaces of the insulating patterns 340. In other words, the channel region and the bulk region may not be separated. In these embodiments, carriers can be sufficiently supplied from the bulk region to the channel regions, so that it is possible to increase the possibility of a relatively lower channel resistance. Furthermore, it can be expected that a back bias voltage V_{bb} applied to the bulk portion of the substrate 310 lowers the threshold voltage Vₜ of a transistor.

Furthermore, FIG. 3 illustrates a case in which the insulating patterns 340 is formed to have a relatively lower height “h3.” It means that the height of the insulating patterns 340 may be adjusted depending on the characteristics of a desired semiconductor device. In these embodiments, the heat radiation characteristic of the device may be improved.

Furthermore, FIG. 3 illustrates embodiments in which the widths “W3” and “W4” of the insulating patterns 340 are formed to be wider than those in the semiconductor devices 100 and 200 shown in FIGS. 1 and 2, respectively. In other words, the space “S2” between the insulating patterns 340 shown in FIG. 3 is formed to be narrower than those in the semiconductor devices 100 and 200 shown in FIGS. 1 and 2, respectively. In these embodiments, as described above, the leakage current characteristics of the semiconductor device 300 is improved.

As further illustrated in FIG. 3, the insulating patterns 340 are aligned with gate spacers 339. However, it is not essential for the insulating patterns 340 to be aligned with the gate spacers 339. It will be understood that FIG. 3 is an exemplary view for a better understanding of the technical aspects of some embodiments of the present invention only. The semiconductor device 300 according to some embodiments of the present invention has no discontinuity in a crystal structure face, at least in the channel region.

Referring now to FIG. 4, a cross-section illustrating a semiconductor device according to some embodiments of the present invention will be discussed. As illustrated in FIG. 4, the semiconductor device 400 according to some embodiments of the present invention includes gate patterns 430 on a substrate 410, isolation regions 420, an insulating pattern 440, and source/drain regions 450.

According to the semiconductor device 400 based on some embodiments of the present invention, one insulating pattern 440 may be formed in one separate active region, differently from insulating patterns according to the embodiments of the present invention shown in FIGS. 1 through 3.

One of the aspects of the present invention is to form no discontinuity in the crystal structure of the channel region, which will be discussed further herein. The semiconductor device 400 according to some embodiments of the present invention has no discontinuity in the crystal structure of the channel region, and allows a discontinuity to be formed in the source/drain regions 450.

Furthermore, according to the semiconductor device 400 based on some embodiments of the present invention, since the insulating pattern 440 isolates the channel regions from the bulk region of the substrate 410 over a wide region, the leakage current can be further reduced.

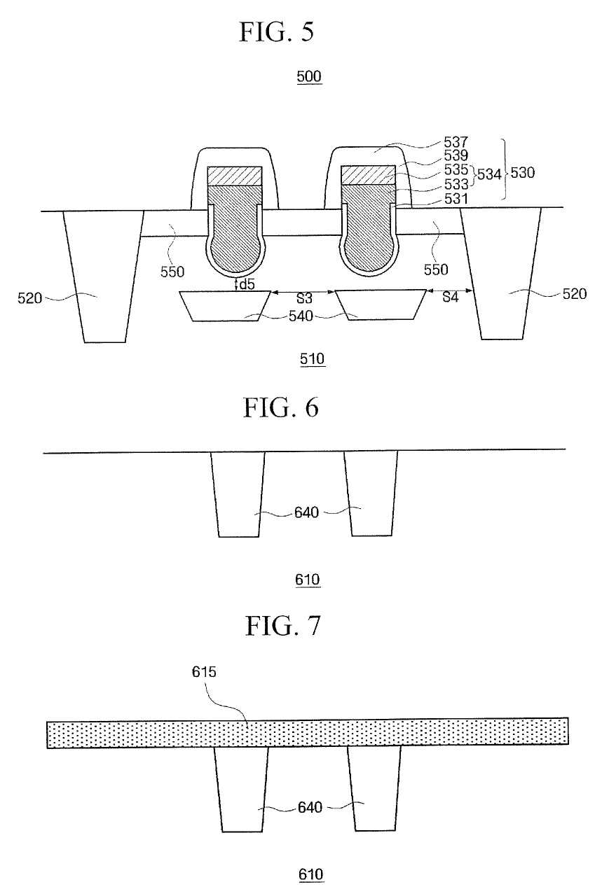

Referring now to FIG. 5 is a cross-section illustrating a semiconductor device according to some embodiments of the present invention. As illustrated in FIG. 5, the semiconductor device 500 according to some embodiments of the present invention includes recessed channel array transistor (RCAT) gate patterns 530, isolation regions 520, insulating patterns 540, and source/drain regions 550.

The semiconductor device according to some embodiments of the present invention includes an RCAT. Therefore, the insulating patterns 540 may be formed at deep locations in the substrate 510 in accordance with the depth of the RCAT. A fifth distance “d5,” which is a distance between the lowest end of the gate insulating layers 531 in the RCAT gate patterns 530 and the top surfaces of the insulating patterns 540, may be variously established depending on the characteristics of devices. Therefore, in some embodiments of the present invention, a detailed numeral for the fifth distance “d5” will not be described. Furthermore, various shapes of the RCAT gate patterns 530 and methods for forming the same is generally known in the art, so a detailed description thereof will be omitted. FIG. 5 illustrates the RCAT gate patterns 530 having a relatively simple shape for a better understanding of the technical aspects of some embodiments of the present invention only.

Hereinafter, a method of manufacturing a semiconductor device having an insulating pattern within a substrate according to some embodiments of the present invention will be described. FIGS. 6 through 16 are cross sections illustrating processing steps in the manufacturing of semiconductor devices having an insulating pattern within a substrate thereof according to some embodiments of the present invention.

Referring now to FIG. 6, insulating patterns 640 are formed within a substrate 610. The substrate 610 may include silicon (Si) or silicon-germanium (SiGe) material. The insulating patterns 640 may be formed by a well-known STI region forming method. Tile insulating patterns 640 may include a single layered insulating material, or may include a multi layered insulating material by forming a liner (not shown) at an interface between the insulating patterns 640 and the substrate 610. According to some embodiments of the present invention, the insulating patterns 640 may include a silicon oxide layer. The STI region forming method is known, so a detailed description thereof will be omitted.

Referring now to FIG. 7, a silicon layer 615 is formed on the substrate 610 and insulating patterns 640. According to some embodiments of the present invention, the silicon layer 615 may include amorphous silicon, and may include means of a deposition method or epitaxial growth method. As illustrated and described in FIGS. 1 through 5, the thickness of the silicon layer 615 may vary depending on the depth “d1,” “d2,” “d3,” “d4,” or “d5,” either from the surface of the substrate 110, 210, 310, 410 or 510 or from the bottom ends of the gate insulating layers 131, 231, 331, 431 or 531, to the top surfaces of the insulating patterns 140, 240, 340, 440 or 540.

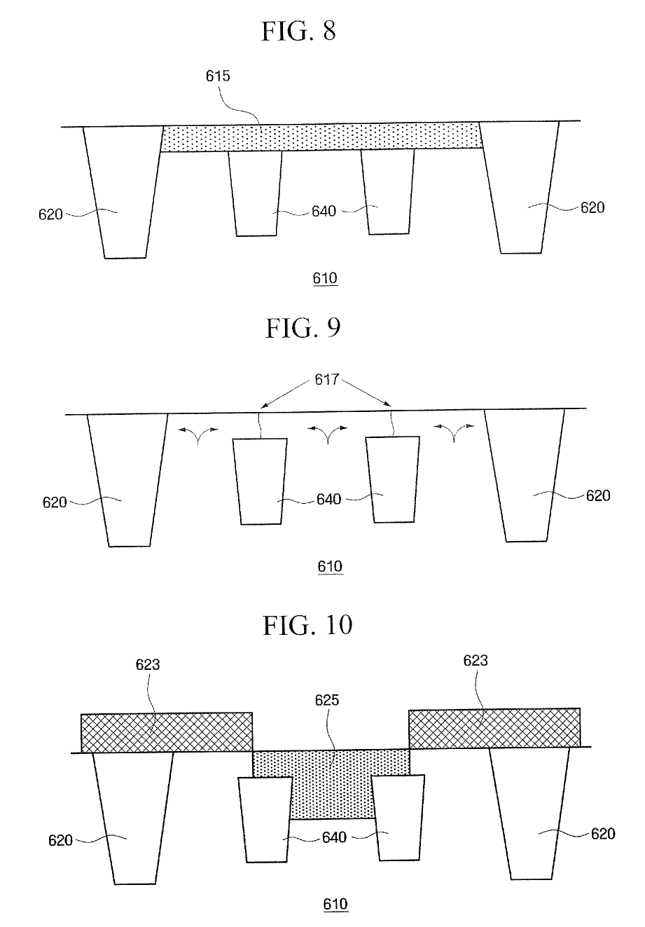

Referring now to FIG. 8, isolation regions 620 are formed in the substrate 610. According to some embodiments of the present invention, the isolation regions 620 may be formed by the STI forming method. As described above, the STI forming method is known, so a detailed description thereof will be omitted. For reference, the isolation regions 620 may be formed up to a location deeper than the bottom ends of the insulating patterns 640.

Referring now to FIG. 9, the silicon layer 615 is polycrystallized to have the equivalent to crystal structure of the substrate 610. When the silicon layer 615 has been polycrystallized to have the equivalent to crystal structure of the substrate 610, the interface between the silicon layer 615 and the substrate 610 disappears. In some embodiments, the polycrystallization reaction is progressed in the directions indicated by arrows in FIG. 9. When the polycrystallization reaction is progressed in the arrow directions, first discontinuous faces 617 corresponding to a discontinuity in a crystal structure may be formed at a position where polycrystallization reactions progressed from both sides collide with each other.

When the silicon layer 615 is made of amorphous silicon, the polycrystallization reaction may be regarded as a crystallization reaction. That is, the polycrystallization reaction may be regarded as a reaction to transform an amorphous material layer into a crystalline material layer.

Various methods of deriving a polycrystallization reaction or crystallization reaction are well known. For example, the amorphous layer may be heat treated, or a laser beam may be irradiated to the amorphous silicon. Particularly, according to some embodiments of the present invention, a method of irradiating a laser beam may be used to transform an amorphous layer into a crystalline layer. The method of irradiating a laser beam in order to transform an amorphous layer into a crystalline layer is relatively profitable to derive a crystallization reaction that gives high energy to the surface of an amorphous layer. Since it is easy to apply energy to only a region where an amorphous layer has been formed instead of applying energy to the overall bulk, some embodiments the present invention may also use a laser beam irradiation method in order to perform a crystallization reaction. Various laser beam irradiation methods are generally known.

Referring now to FIG. 10, a mask pattern 623 is formed and then an amorphous region 625 is formed. In particular, the mask pattern 623 is formed by a photoresist pattern or the like, and then the inside of an exposed region of the substrate 610 is amorphized through an ion implantation method. That is, it can be understood that a crystalline crystal stricture is physically destroyed to be amorphized. The amorphous region 625 may correspond to a part of the region between the insulating patterns 640, and may correspond to a region located on top of a part of the insulating patterns 640. A detailed shape of the amorphous region 625 may be understood with reference to FIG. 10.

Ions implanted to form the amorphous region 625 include silicon or germanium ions. Thereafter, the mask pattern 623 is removed.

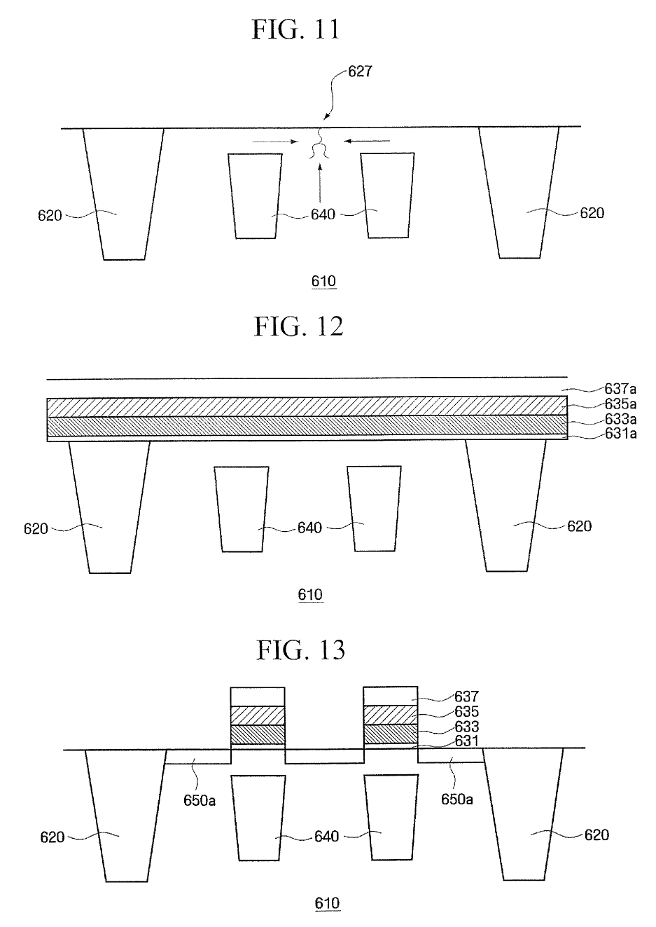

Referring now to FIG. 11, a crystallization reaction is performed to recrystallize the amorphous region 625. In these embodiments, any interface between the crystalline region and the amorphous region disappears. Furthermore, since the crystallization reaction is progressed in the directions indicated by arrows in FIG. 11, second discontinuous faces 627 corresponding to a discontinuity in a crystal structure may be formed at or around a position indicated by reference numeral 627 in FIG. 11. The second discontinuous faces 627 may be formed in three directions.

According to some embodiments of the present invention, the first discontinuous faces 617 are formed on top of the insulating patterns 640. The first discontinuous faces 617 are located in a region in which the channel of a transistor will be formed in the future. Since the channel regions are very susceptible, it is undesirable that faces having a discontinuity in a crystal structure exist in the channel regions. Therefore, some embodiments of the present invention, completely remove the first discontinuous face 617, and allows the second discontinuous faces 627 to be formed in a region in which channels will not be formed, so that the channels of transistors cannot be affected by any discontinuous face. When an amorphous structure is crystallized, it is inevitable for a discontinuous in a crystal structure to be formed unless the crystallization reaction is derived only in a single direction. In this case, it is important to prevent the discontinuity in a crystal structure from being formed in channel regions at least.

When this is considered, a discontinuity in the crystal structure of the semiconductor device 400 according to some embodiments of the present invention, shown in FIG. 4, is formed not in the channel regions beneath the gate patterns 430 but between the gate patterns 430 within the substrate 410.

According to some embodiments of the present invention, when ions implanted to form the amorphous region 625 are germanium ions, a following crystallization process may transform the amorphous region 625 into a silicon germanium (SiGe) crystal structure.

A silicon germanium region can be selectively removed separately from other regions, for example, a silicon layer, a silicon oxide layer, a silicon nitride layer, and the like, can be epitaxially grown, and enables the mobility of carriers to be controlled. Therefore, according to some embodiments of the present invention, when germanium ions are injected, it is possible to vary the characteristics of channels. That is, it is unnecessary to implant separate geranium ions and to perform an epitaxial growth process for a silicon germanium layer in order to change the characteristics of channels.

Referring now to FIG. 12, a first insulating layer 631a, a first conductive layer 633a, a second conductive layer 635a and a second insulating layer 637a are formed on the substrate 610 in which the isolation regions 620 and insulating patterns 640 have been formed.

The first insulating layer 631a may be used to form a gate insulating layer, and may include insulating material, such as a silicon oxide layer, an aluminum oxide layer or a hafnium oxide layer.

The first conductive layer 633a may be used to form a lower electrode of a gate, and may include polycrystalline silicon. Furthermore, when the first conductive layer 633a includes silicon, ions may be implanted into the first conductive layer 633a so as to give conductivity thereto.

The second conductive layer 635a may be used to form an upper electrode of the gate, and may include metal or metallic silicide. The second insulating layer 637a may function as a gate-patterning mask for patterning the gate, and may include silicon nitride layers. FIG. 12 and the description thereof have been conceptionally and generally illustrated and explained for a better understanding of the technical aspects of the present invention only. Therefore, it is not essential to separately form the conductive layer for gate electrodes for the upper electrode and lower electrode. The gate electrode may include one conductive layer, or be formed in a shape including three or more different material layers laminated together.

Referring now to FIG. 13, a photoresist pattern (not shown) for gate patterning is formed, shapes of gate are formed, and then a first ion implantation is performed through an exposed surface of the substrate 610, so that first ion-implantation regions 650a are formed.

The photolithography and patterning process to form a shape of gate is generally sown, so a detailed description thereof will be omitted.

The first ion-implantation regions 650a may be regions in which ions have been implanted with a relatively low concentration so as to form shapes of final source/drain regions having lightly doped drain (LDD) or double doped drain (DDD) structures. The method of forming the first ion-implantation regions 650a is generally known, so a detailed description thereof will be omitted.

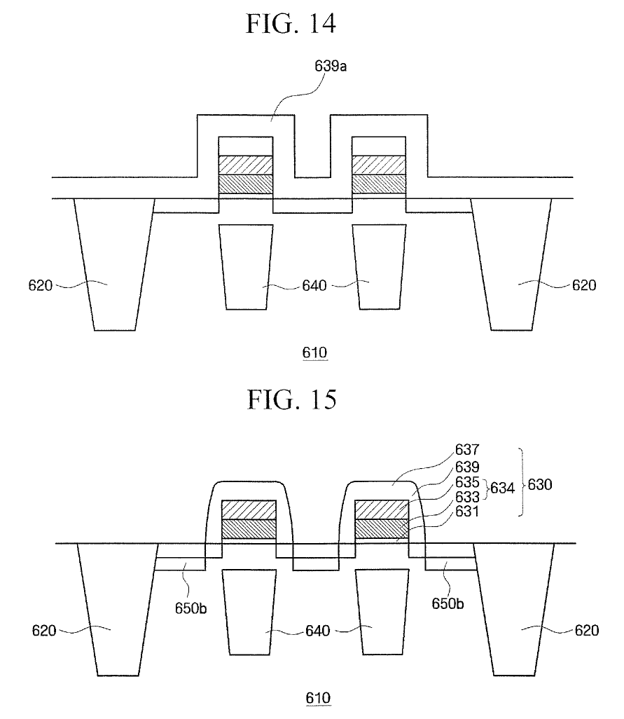

Referring now to FIG. 14, a third insulating layer 639a is formed on the entire surface of a resultant structure shown in FIG. 13. The third insulating layer 639a may be used to form gate spacers, and simultaneously, may be used to supplement lowered gate capping layers. The third insulating layer 639a may be formed by a deposition scheme, particularly, by the Chemical Vapor Deposition (CVD) scheme.

Referring now to FIG. 15, gate spacers 639 are formed, thereby completing gate patterns 630. In particular, a blanket etch or etch-back process for forming the gate spacers 639 is performed with respect to the entire surface of a resultant structure shown in FIG. 14, thereby forming the gate spacer 639.

Then, a second ion implantation is preformed through an exposed surface of the substrate, thereby forming second ion implantation regions 650b. The second ion implantation regions 650b are regions in which ions have been implanted with a higher concentration than the first ion implantation regions 650a.

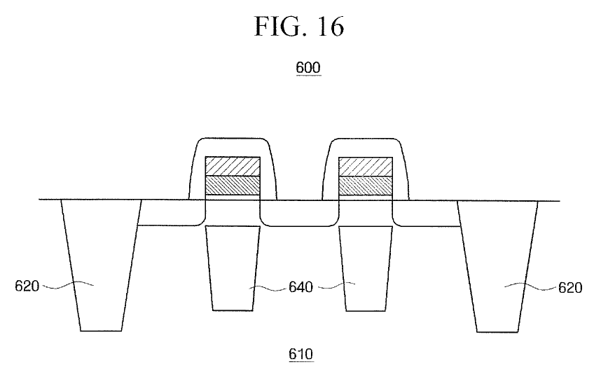

Referring now to FIG. 16, ions implanted into the first ion implantation regions 650a and second ion implantation regions 650b are thermally diffused, thereby forming final source/drain regions 650. The thermal diffusion method for implanted ions is well known, so a detailed description thereof will be omitted.

Through various combinations of the width, height, depth and interval of the insulating patterns 640, energy to implant ions, doses, etc. based on the method of manufacturing the semiconductor device according to some embodiments of the present invention, it is possible to manufacture semiconductor devices 100, 200, 300, 400 and 500 according to the first to third embodiments of the present invention.

In addition, when an RCAT gate forming method is additionally used, it is possible to manufacture the semiconductor device 500 according to some embodiments of the present invention.

As discussed above, according to the semiconductor devices according to some embodiments of the present invention and related methods of manufacturing the same, insulating patterns are formed only beneath the channel region of a transistor, so that it is possible to easily manufacture a semiconductor device which causes only a small amount of leakage current in the transistor, has an excellent heat radiation capability, and can control even the threshold value Vt of the transistor.

Although exemplary embodiments of the present invention have been described for illustrative purposes, those skilled in the art will appreciate that various modifications, additions and substitutions are possible, without departing from the scope and spirit of the invention as disclosed in the accompanying claims. Therefore, it should be appreciated that the embodiments described above are not limitative, but only illustrative.

That which is claimed is:

1. A semiconductor device comprising:
gate patterns on a substrate;
isolation regions in the substrate;
insulating patterns in the substrate, the insulating patterns being below the gate patterns; and
source/drain regions in the substrate.

2. The semiconductor device of claim 1, wherein bottom surfaces of the insulating patterns are relatively closer to a surface of the substrate than bottom surfaces of the isolation regions.

3. The semiconductor device of claim 1, wherein upper surfaces of the insulating patterns are spaced apart by a first distance from a surface of the substrate.

4. The semiconductor device of claim 3, wherein a channel region is formed in the spaced apart regions having the first distance.

5. The semiconductor device of claim 4, wherein the first distance is electrically isolated from a bulk region of the substrate.

6. The semiconductor device of claim 1, wherein the insulating patterns have an upper horizontal width and a lower horizontal width, the upper horizontal width being longer than the lower horizontal width.

7. The semiconductor device of claim 1, wherein the insulating patterns have an island shape.

8. The semiconductor device of claim 7, wherein the insulating patterns have a wider width than a width of a gate electrode of each of the gate patterns.

9. The semiconductor device of claim 1, wherein bottom surfaces of the source/drain regions are deeper toward an interior of the substrate than upper surfaces of the insulating patterns.

10. The semiconductor device of claim 1, wherein the insulating patterns are aligned with the gate patterns.

11. A method for manufacturing a semiconductor device, the method comprising(:
forming insulating patterns in a substrate;
forming an amorphous silicon layer on the substrate and the insulating patterns;
forming isolation regions in the substrate;
performing a first crystallization process to crystallize the amorphous silicon layer;
amorphizing a part of the crystallized silicon layer and a part of the substrate;
performing a second crystallization process to crystallize a part of the amoiphized silicon layer and a part of the substrate;
forming gate patterns on the substrate; and
forming source/drain regions within the substrate.

12. The method of claim 11, wherein bottom surfaces of the insulating patterns is closer to a surface of the substrate than bottom surfaces of the isolation regions.

13. The method of claim 11, wherein upper surfaces of the insulating patterns are spaced apart by a first distance from a surface of the substrate.

14. The method of claim 13, further comprising forming a channel region in the spaced apart region having the first distance.

15. The method of claim 14, wherein the first distance is electrically isolated from a bulk region of the substrate.

16. The method of claim 11, wherein the insulating patterns have an upper horizontal width and a lower horizontal width, the upper horizontal width being longer than the lower horizontal width.

17. The method of claim 11, wherein the insulating patterns have an island shape.

18. The method of claim 17, wherein the insulating patterns have a wider width than a width of a gate electrode of each of the gate patterns.

19. The method of claim 11, wherein bottom surfaces of the source/drain regions extend deeper toward an interior of the substrate than upper surfaces of the insulating patterns.

20. The method of claim 11, wherein the insulating patterns are aligned with the gate patterns.
